(19) United States
(12) Patent Application Publication
(10) Pub. No.: US 2023/0162103 A1
(43) Pub. Date: May 25, 2023

(54) OPERATION CONDITION SETTING DEVICE, PEOPLE FLOW PREDICTION DEVICE, OPERATION CONDITION SETTING METHOD, PEOPLE FLOW PREDICTION METHOD, AND PROGRAM

(71) Applicant: MITSUBISHI HEAVY INDUSTRIES, LTD., Tokyo (JP)

(72) Inventors: Kazuki Yoshida, Tokyo (JP); Masahiro Yamada, Tokyo (JP); Meead Saberi, Sydney (AU); Tanapon Lilasathapornkit, Sydney (AU)

(73) Assignee: MITSUBISHI HEAVY INDUSTRIES, LTD., Tokyo (JP)

(21) Appl. No.: 18/058,123

(22) Filed: Nov. 22, 2022

(30) Foreign Application Priority Data
Nov. 25, 2021 (JP) 2021-191343

(51) Int. Cl. G06Q 10/0631

(52) U.S. Cl. CPC G06Q 10/0631

(57) ABSTRACT

An operation condition setting device includes a calculation unit calculating a predictive waypoint-pass-through value as a predictive value of the number of people passing through a waypoint at a predetermined time in a future and is calculated in consideration that an arrival time to the waypoint deviates from a reference arrival time to the waypoint, a people flow information setting unit setting, based on the predictive waypoint-pass-through value, people flow information indicating a flow of people, and an operation condition setting unit calculating, based on a facility model including nodes each corresponding to respective points and a link connecting the nodes and the people flow information, a movement route of each of the people passing through the waypoint in the facility model and an operation condition of a vehicle, by performing optimization calculation and setting the operation condition of the vehicle.

### CROSS-REFERENCE TO RELATED APPLICATIONS

This application claims the benefit of priority to Japanese Patent Application Number 2021-191343 filed on Nov. 25, 2021. The entire contents of the above-identified application are hereby incorporated by reference.

### TECHNICAL FIELD

The disclosure relates to an operation condition setting device, a people flow prediction device, an operation condition setting method, a people flow prediction method, and a program.

### RELATED ART

Vehicle transportation systems that operate between points in, for example, an airport are known. JP 2000-264210 A describes such a vehicle transportation system in which a vehicle operation schedule is set based on a transportation demand of passengers.

### SUMMARY

However, to efficiently set a vehicle operation schedule, it is necessary to increase the predictive accuracy of a people flow related to the number of passengers. Highly accurate prediction of the people flow is also demanded for purposes other than setting of a vehicle operation schedule.

The disclosure is contrived to solve the above problem, and an object of the disclosure is to provide an operation condition setting device, a people flow prediction device, an operation condition setting method, a people flow prediction method, and a program that can predict people flow with high accuracy.

In order to solve the above problem and achieve the object, an operation condition setting device according to the disclosure is an operation condition setting device setting an operation condition of a vehicle transporting people between predetermined points in a facility including a waypoint where people pass and includes a predictive waypoint-pass-through value calculation unit calculating a predictive waypoint-pass-through value, which is a predictive value of the number of people passing through the waypoint at a predetermined time in a future and is calculated in consideration that an arrival time to the waypoint deviates from a reference arrival time to the waypoint, a people flow information setting unit setting, based on the predictive waypoint-pass-through value, people flow information indicating a flow of people in the facility, and an operation condition setting unit calculating, based on a facility model including nodes each corresponding to respective points in the facility and a link connecting the nodes and the people flow information, a movement route for each of the people passing through the waypoint in the facility model and the operation condition of the vehicle, by performing optimization calculation and setting the operation condition of the vehicle.

In order to solve the above problem and achieve the object, a people flow prediction device according to the disclosure is a people flow prediction device predicting, in a facility including a waypoint where people pass, the number of people passing through the waypoint at a predetermined time in a future and includes a predictive value acquisition unit acquiring at least one of a first predictive value, which is a predictive value of the number of people located at a first point upstream from the waypoint in a movement direction of people before the predetermined time, or a second predictive value, which is a predictive value of the number of people located at a second point downstream from the waypoint in the movement direction of the people after the predetermined time, and a predictive waypoint-pass-through value calculation unit calculating a predictive waypoint-pass-through value, which is a predictive value of the number of people passing through the waypoint at the predetermined time, based on at least one of the first predictive value or the second predictive value. The predictive waypoint-pass-through value calculation unit calculates the predictive waypoint-pass-through value based on respective predictive values of the numbers of people located at the first point at different times before the predetermined time and an influence degree, on the predictive waypoint-pass-through value, set for each of the predictive values at the different times before the predetermined time and calculates the predictive waypoint-pass-through value based on respective predictive values of the numbers of people located at the second point at different times after the predetermined time and an influence degree, on the predictive waypoint-pass-through value, set for each of the predictive values at the different times after the predetermined time.

In order to solve the above problem and achieve the object, an operation condition setting method according to the disclosure is an operation condition setting method of setting an operation condition of a vehicle transporting people between predetermined points in a facility including a waypoint where people pass and includes calculating a predictive waypoint-pass-through value, which is a predictive value of the number of people passing through the waypoint at a predetermined time in a future and is calculated in consideration that an arrival time to the waypoint deviates from a reference arrival time to the waypoint, setting, based on the predictive waypoint-pass-through value, people flow information indicating a flow of people in the facility, setting, based on a facility model including nodes each corresponding to respective points in the facility and a link connecting the nodes and the people flow information, a movement route of people in the facility model for each of the people passing through the waypoint, and setting the operation condition of the vehicle by calculating the operation condition of the vehicle in the facility model through optimization calculation based on the movement route.

In order to solve the above problem and achieve the object, a people flow prediction method according to the disclosure is a people flow prediction method of predicting, in a facility including a waypoint where people pass, the number of people passing through the waypoint at a predetermined time in a future and includes acquiring at least one of a first predictive value, which is a predictive value of the number of people located at a first point upstream from the waypoint in a movement direction of people before the predetermined time, or a second predictive value, which is a predictive value of the number of people located at a second point downstream from the waypoint in the movement direction of the people after the predetermined time, and calculating a predictive waypoint-pass-through value, which is a predictive value of the number of people passing through the waypoint at the predetermined time, based on at least one of the first predictive value or the second predictive value. In the calculating, the predictive waypoint-pass-through value is calculated based on respective predictive values of the numbers of people located at the first point at different times before the predetermined time and an influence degree, on the predictive waypoint-pass-through value, set for each of the predictive values at the different times before the predetermined time, and the predictive waypoint-pass-through value is calculated based on respective predictive values of the numbers of people located at the second point at different times after the predetermined time and an influence degree, on the predictive waypoint-pass-through value, set for each of the predictive values at the different times after the predetermined time.

In order to solve the above problem and achieve the object, a program according to the disclosure is a program for causing a computer to execute an operation condition setting method of setting an operation condition of a vehicle transporting people between predetermined points in a facility including a waypoint where people pass and causes the computer to execute calculating a predictive waypoint-pass-through value, which is a predictive value of the number of people passing through the waypoint at a predetermined time in a future and is calculated in consideration that an arrival time to the waypoint deviates from a reference arrival time to the waypoint, setting, based on the predictive waypoint-pass-through value, people flow information indicating a flow of people in the facility, setting, based on a facility model including nodes each corresponding to respective points in the facility and a link connecting the nodes and the people flow information, a movement route of people in the facility model for each of the people passing through the waypoint, and setting the operation condition of the vehicle by calculating the operation condition of the vehicle in the facility model through optimization calculation based on the movement route.

In order to solve the above problem and achieve the object, a program according to the disclosure is a program for causing a computer to execute a people flow prediction method of predicting, in a facility including a waypoint where people pass, the number of people passing through the waypoint at a predetermined time in a future and causes the computer to execute acquiring at least one of a first predictive value, which is a predictive value of the number of people located at a first point upstream from the waypoint in a movement direction of people before the predetermined time, or a second predictive value, which is a predictive value of the number of people located at a second point downstream from the waypoint in the movement direction of the people after the predetermined time, and calculating a predictive waypoint-pass-through value, which is a predictive value of the number of people passing through the waypoint at the predetermined time, based on at least one of the first predictive value or the second predictive value. In the calculating, the predictive waypoint-pass-through value is calculated based on respective predictive values of the numbers of people located at the first point at different times before the predetermined time and an influence degree, on the predictive waypoint-pass-through value, set for each of the predictive values at the different times before the predetermined time, and the predictive waypoint-pass-through value is calculated based on respective predictive values of the numbers of people located at the second point at different times after the predetermined time and an influence degree, on the predictive waypoint-pass-through value, set for each of the predictive values at the different times after the predetermined time.

According to the disclosure, a people flow can be predicted with high accuracy.

### BRIEF DESCRIPTION OF DRAWINGS

The disclosure will be described with reference to the accompanying drawings, wherein like numbers reference like elements.

FIG. 1 is a schematic view for describing a facility.

FIG. 2 is a schematic block diagram of an operation condition setting device according to the present embodiment.

FIG. 3 is a schematic view illustrating an example of a facility model.

FIG. 4 is a flowchart for describing processing flow of the operation condition setting device according to the present embodiment.

FIG. 5 is a schematic block diagram of a people flow prediction device.

FIG. 6 is a table showing examples of values of influence degrees for each time slot of a predetermined time.

### DESCRIPTION OF EMBODIMENTS

Preferred embodiments of the disclosure will be described in detail below with reference to the accompanying drawings. Note that the disclosure is not limited to these embodiments, and, when there are a plurality of embodiments, the disclosure is intended to include a configuration combining these embodiments.

### First Embodiment

An operation condition setting device 100 according to the present embodiment is a device setting an operation condition of a vehicle TR. The vehicle TR transports people U being passengers in a facility F. First, the facility F will be described.

### Facility

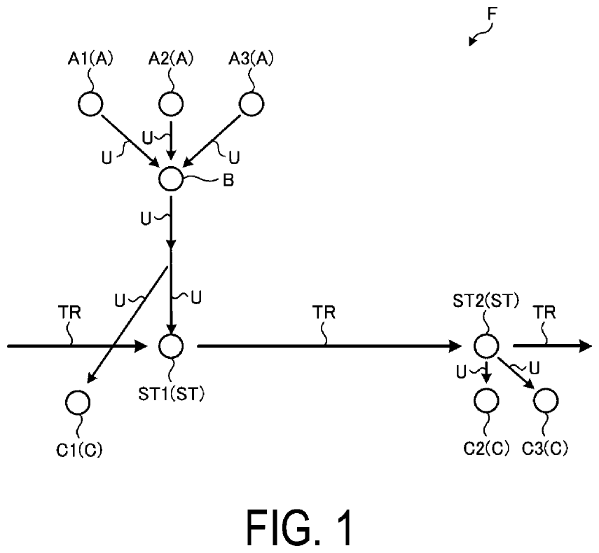

FIG. 1 is a schematic view for describing the facility. As illustrated in FIG. 1, the facility F is a facility including a waypoint B through which the people U pass. That is, in the facility F, each of the people U travels from a departure point to an arrival point via the waypoint B. The departure point refers to a position where each of the people U starts moving in the facility F (start point). The arrival point refers to a position where each of the people U finishes moving in the facility F (goal point). The departure point and the arrival point are set for each of the people U. In addition, the waypoint B refers to a point through which the people U pass during movement in the facility F (relay point). It can be said that the waypoint B is located between the departure point and the arrival point in the movement direction of the people U. The waypoint B is set in common for the plurality of people U, and the plurality of people U pass through the same waypoint B. However, the waypoint B may not be set in common for all of the people U in the facility F, and a plurality of the waypoints B may be set in the facility F. In this case, some of the plurality of people U pass through one of the waypoints B, and the others of the plurality of people U pass through the others of the waypoints B.

The facility F includes a first point A upstream from the waypoint B in the movement direction of the people U and a second point C downstream from the waypoint B in the movement direction of the people U. A plurality of the first points A and a plurality of the second points C are provided in the facility F. Each of the people U moves from one first point A among the plurality of first points A to one second point C among the plurality of second points C via the waypoint B. That is, one of the plurality of first points A is a departure point of any of the people U, and one of the plurality of second points C is an arrival point of any of the people U.

In addition, the vehicle TR moving between points ST being stations is provided in the facility F. The vehicle TR moves while allowing the people U to get thereon as the passengers, thereby transporting the people U between the points ST. The vehicle TR may be any type of vehicle, and examples thereof may include a bus and a train.

In the present embodiment, the facility F is an airport, and the waypoint B is a security check point in the airport. The security check point refers to a point through which the plurality of people U pass, such as a baggage inspection area or a passport control area. In addition, the first point A is a transfer gate in the present embodiment, but the embodiment is not limited thereto. For example, the first point A may be at least one of a transfer gate or an entrance of the facility F (entrance of the airport). The transfer gate refers to a gate through which a passenger who has arrived at the facility F by airplane and is transferring to another airplane in the facility F enters the facility F from the airplane having arrived at the facility F. The entrance of the facility F refers to a gate through which a person who has arrived at the facility F without using an airplane enters the facility F. In addition, each second point C is a departure gate in the present embodiment, but the embodiment is not limited thereto. For example, each second point C may be at least one of a departure gate or an exit of the facility F (exit of the airport). The departure gate refers to a boarding gate for an airplane departing from the facility F. The exit of the facility F refers to a gate through which a person leaving the facility F without using an airplane exits from the facility F.

Note that the first point A as the transfer gate may be a transfer gate where a domestic airplane arrives or a transfer gate where an international airplane arrives. Similarly, the second point C as the departure gate may be a departure gate where a domestic airplane departs or a departure gate where an international airplane departs. That is, the waypoint B may be a security check point for transfer between domestic flights, a security check point for transfer between international flights, a security check point for transfer from a domestic flight to an international flight, or a security check point for transfer from an international flight to a domestic flight.

However, the facility F is not limited to the airport and may be any facility. The waypoint B also is not limited to the security check point and may be any point. The first point A also is not limited to the transfer gate or the entrance of the facility F and may be any point. The second point C also is not limited to the departure gate or the exit of the facility F and may be any point.

In the example illustrated in FIG. 1, the first points A1, A2, and A3 are provided as the first point A, and the second points C1, C2, and C3 are provided as the second point C. Each of the first points A1, A2 and A3 is connected to the waypoint B via a passage. The waypoint B is also connected to each of the second points C1, C2, and C3 via a passage or the like. Specifically, points ST1 and ST2 being stations are provided on a side where the second point C is present from the waypoint B (downstream from the waypoint B in the movement direction of the people U), and the vehicle TR operates between the points ST1 and ST2. The second point C1 is connected to the waypoint B via a passage without via an operation route of the vehicle TR between the points ST1 and ST2. On the other hand, the second points C2 and C3 are each connected to the waypoint B via the operation route of the vehicle TR between the points ST1 and ST2. In the example of FIG. 1, each of the people U moves to the waypoint B from any of the first points A1, A2, and A3 as the departure point. Then, each of the people U passes through the waypoint B and moves, with any of the second points C1, C2, and C3 as an arrival point, from the waypoint B to the arrival point. In this case, one of the people U moving to the second point C1 moves from the waypoint B to the second point C1 through the passage without getting on the vehicle TR. On the other hand, another one of the people U moving to the second point C2 or C3 moves from the waypoint B to the point ST1, gets on the vehicle TR from the point ST1, and is transported to the point ST2 by the vehicle TR. Then, another one of the people U gets off from the vehicle TR at the point ST2 and moves to the second point C2 or C3 through a passage from the point ST2.

However, the configuration of the facility F in FIG. 1, that is, the arrangement of the respective points is an example, and the arrangement and the number of the respective points may be freely determined. For example, the point ST being a station, that is, the operation route of the vehicle TR is not limited to being arranged on the side where the second point C is present from the waypoint B (downstream from the waypoint B in the movement direction of the people U) and may be arranged on a side where the first point A is present from the waypoint B (upstream from the waypoint B in the movement direction the people U) or may be located both downstream and upstream from the waypoint B. In addition, the facility F may include any point by which the people U drop, in addition to the point ST, the first point A, the waypoint B, and the second point C. Examples of the point by which the people U drop include a store. In this case, the people U may pass through the drop-by-point while moving from the first point A to the second point C through the waypoint B. The first point A may be the same as the waypoint B.

### Operation Condition Setting Device

The operation condition setting device 100 sets an operation condition of the vehicle TR provided in such a facility F. The operation condition setting device 100 can appropriately set the operation condition of the vehicle TR by using a predictive value (predictive waypoint-pass-through value) of the number of the people U passing through the waypoint B, which is calculated in consideration that an arrival time to the waypoint B deviates from a schedule, to predict a people flow with high accuracy. The operation condition setting device 100 will be described below.

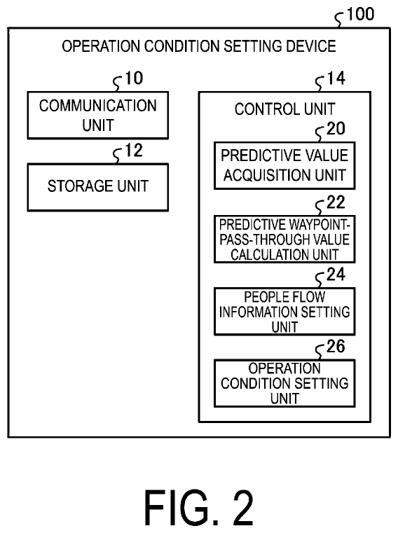

FIG. 2 is a schematic block diagram of the operation condition setting device according to the present embodiment. As illustrated in FIG. 2, the operation condition setting device 100 includes a communication unit 10, a storage unit 12, and a control unit 14. The operation condition setting device 100 may further include an input unit receiving an input from a user (e.g., a mouse and a keyboard), and an output unit outputting information (e.g., a display panel and a speaker).

The communication unit 10 is a communication module that communicates with an external device, and is, for example, an antenna or a Wi-Fi (trade name) module. The operation condition setting device 100 performs wireless communication with the external device, but may perform wired communication, and any communication method may be used.

The storage unit 12 is a memory that stores various types of information such as a computation content and a program of the control unit 14, and includes, for example, at least one of a primary storage device such as a Random Access Memory (RAM) or a Read Only Memory (ROM), or an external storage device such as a Hard Disk Drive (HDD). The program for the control unit 14 stored in the storage unit 12 may be stored in a recording medium that is readable by the operation condition setting device 100.

The control unit 14 is an arithmetic device and includes an arithmetic circuit such as a Central Processing Unit (CPU). The control unit 14 includes a predictive value acquisition unit 20, a predictive waypoint-pass-through value calculation unit 22, a people flow information setting unit 24, and an operation condition setting unit 26. The control unit 14 reads and executes the program (software) from the storage unit 12 to implement the predictive value acquisition unit 20, the predictive waypoint-pass-through value calculation unit 22, the people flow information setting unit 24, and the operation condition setting unit 26 and executes the processing of those units. Note that the control unit 14 may execute such processing with a single CPU or may include a plurality of CPUs and execute the processing with the plurality of CPUs. In addition, at least a part of processing of the predictive value acquisition unit 20, the predictive waypoint-pass-through value calculation unit 22, the people flow information setting unit 24, and the operation condition setting unit 26 may be implemented by a hardware circuit.

### Predictive Value Acquisition Unit

### Acquisition of First Predictive Value

The predictive value acquisition unit 20 acquires a first predictive value, which is a predictive value of the number of the people U located at the first point A in the future. In the present embodiment, as to be described below, the predictive waypoint-pass-through value calculation unit 22 calculates a predictive waypoint-pass-through value, which is a predictive value of the number of the people U passing through the waypoint B at a predetermined time tin the future. To calculate the predictive waypoint-pass-through value at the predetermined time t, the predictive value acquisition unit 20 acquires the first predictive value of the number of people located at the first point A at a past time after the present time and before (earlier than) the predetermined time t. In the present embodiment, the plurality of first points A are present, and thus the predictive value acquisition unit 20 acquires the first predictive value for each of the plurality of first points A at the past times.

More specifically, the predictive value acquisition unit 20 acquires the respective first predictive values at different times before the predetermined time t. In other words, the predictive value acquisition unit 20 sets the plurality of past times and acquires the first predictive value of the number of people located at the first point A at each past time. Examples of the past times may include 2 hours, 3 hours, and 4 hours before the predetermined time t. However, the past times may be any times before the predetermined time t, and the number of the set past times is not limited to three and may be one or any number of two or more. Furthermore, in addition to the first predictive value at the past time, the predictive value acquisition unit 20 may also acquire the first predictive value at the predetermined time t (predictive value of the number of people located at the first point A at the predetermined time t).

Note that the predetermined time t here refers to a timing that does not have a time width, but is not limited thereto, and may be treated as a time having a predetermined time width. That is, the predetermined time t may be referred to as a predetermined time slot in the future (predetermined time slot). Similarly, the past time refers to a timing that does not have a time width, but is not limited thereto, and may be treated as a time having a predetermined time width. That is, the past time may be referred to as a predetermined time slot after the present time and before the predetermined time t (past time slot).

### Acquisition of Second Predictive Value

The predictive value acquisition unit 20 acquires second predictive value, which is a predictive value of the number of the people U located at the second point C in the future. To calculate the predictive waypoint-pass-through value at the predetermined time t, the predictive value acquisition unit 20 acquires the second predictive value of the number of people located at the second point C at a future time after the present time and after (later than) the predetermined time t. In the present embodiment, the plurality of second points C are present, and thus the predictive value acquisition unit 20 acquires the second predictive value for each of the plurality of second points C at the future times.

More specifically, the predictive value acquisition unit 20 acquires the respective second predictive values at different times after the predetermined time t. In other words, the predictive value acquisition unit 20 sets the plurality of future times and acquires the second predictive value of the number of people located at the second point C at each future time. Examples of the future times may include 1 hour, 2 hours, 3 hours, and 4 hours after the predetermined time t. However, the future times may be any times after the predetermined time t, and the number of the set future times is not limited to four and may be one or any number of two or more. Furthermore, in addition to the second predictive value at the future time, the predictive value acquisition unit 20 may also acquire the second predictive value at the predetermined time t (predictive value of the number of people located at the second points C at the predetermined time t). The future time refers to a timing that does not have a time width, but is not limited thereto, and may be treated as a time having a predetermined time width. That is, the future time may be referred to as a predetermined time slot after the predetermined time t (future time slot).

The predictive value acquisition unit 20 may acquire the first predictive value and the second predictive value by any method. For example, the predictive value acquisition unit 20 may acquire, from an external device (e.g., an airplane reservation system) and via the communication unit 10, the number of passengers of the airplane arriving at the first point A (transfer gate) in the facility F and the number of passengers of the airplane departing from the second point C (departure gate) in the facility F to acquire the first predictive value and the second predictive value. For example, if the first point A is the entrance of the facility F, the predictive value acquisition unit 20 may acquire the number of people passing through the entrance of the facility F measured in the past and calculate the first predictive value based on the number. Similarly, if the second point C is the exit of the facility F, the predictive value acquisition unit 20 may acquire the number of people passing through the exit of the facility F measured in the past and calculate the second predictive value based on the number.

As described above, the predictive value acquisition unit 20 acquires both the first predictive value and the second predictive value, but the embodiment is not limited thereto. The predictive value acquisition unit 20 may acquire at least one of the first predictive value or the second predictive value.

### Predictive Waypoint-Pass-Through Value Calculation Unit

The predictive waypoint-pass-through value calculation unit 22 acquires the predictive waypoint-pass-through value, which is a predictive value of the number of people passing through the waypoint B at the predetermined time t and is calculated in consideration that an arrival time to the waypoint B deviates from a reference arrival time to the waypoint B. The reference arrival time to the waypoint B is a reference time when a person is predicted to pass through the waypoint B. The reference arrival time may be freely set but may be set based on, for example, a scheduled departure time of an airplane from the second point C, a distance from the waypoint B to the second point C, and a reference movement speed of people. In this case, the reference arrival time may be set as a time when a person should arrive at the waypoint B so as to arrive at the second point C just at the scheduled departure time. In other words, the reference arrival time can be said as a scheduled arrival time (no-leeway scheduled arrival time) to the waypoint B when it is assumed that the arrival time to the second point C is not generous with respect to the scheduled departure time. In this case, for example, a time obtained by subtracting a value obtained by dividing the distance from the waypoint B to the second point C by the reference movement speed of people (movement time from the waypoint B to the second point C) from the scheduled departure time of the airplane may be used as the reference arrival time. Note that the reference movement speed may be freely set. In other words, considering that the arrival time to the waypoint B deviates from the reference arrival time to the waypoint B means that the predictive value of the number of people passing through the waypoint B is calculated in consideration that the time when each of the people U actually arrives at the waypoint B deviates from the no-leeway scheduled arrival time to the waypoint B, that is, in consideration of the deviation of the arrival time. The predictive waypoint-pass-through value calculation unit 22 may acquire the predictive waypoint-pass-through value at the predetermined time t by any method and, in the present embodiment, acquires the predictive waypoint-pass-through value by calculating the predictive waypoint-pass-through value at the predetermined time t based on the first predictive value at the past time and the second predictive value at the future time. Hereinafter, the method of calculating the predictive waypoint-pass-through value will be more specifically described.

The predictive waypoint-pass-through value calculation unit 22 calculates the predictive waypoint-pass-through value at the predetermined time t based on the first predictive value at each of the past times and the second predictive value at each of the future times, assuming that the people U intend to be located at the first point A at each of the past times and the people U intend to be located at the second point C at each of the future times pass through the waypoint B at the predetermined time t. In addition, in the present embodiment, the predictive waypoint-pass-through value calculation unit 22 sets an influence degree for each first predictive value at the corresponding one of the past times and also sets an influence degree for each second predictive value at the corresponding one of the future times. The influence degree is an indicator indicating the degree of influence of the first predictive value or the second predictive value on the predictive waypoint-pass-through value and can be said as a weight for the predictive waypoint-pass-through value. The influence degree may be set to any number from 0 to 1, for example. The predictive waypoint-pass-through value calculation unit 22 calculates the predictive waypoint-pass-through value at the predetermined time t based on the first predictive value at each past time, the influence degree set for each first predictive value, the second predictive value at each future time, and the influence degree set for each second predictive value.

More specifically, the predictive waypoint-pass-through value calculation unit 22 assigns a weight to the first predictive value for each past time and assigns a weight to the second predictive value for each future time, based on the influence degree, and then calculates the average value of the weighted values as the predictive waypoint-pass-through value at the predetermined time t. Specifically, the predictive waypoint-pass-through value calculation unit 22 calculates, for each past time, the product of the total value of the first predictive values of the respective first points A at the past time and the influence degree set for the past time and calculates the total of these calculated values as a first total value. Then, the predictive waypoint-pass-through value calculation unit 22 calculates, for each future time, the product of the total value of the second predictive values of the respective second points C at the future time and the influence degree set for the future time and calculates the total of these calculated values as a second total value. Then, the predictive waypoint-pass-through value calculation unit 22 calculates the total value of the first total value and the second total value as the predictive waypoint-pass-through value at the predetermined time t. That is, in the present embodiment, the predictive waypoint-pass-through value calculation unit 22 calculates a predictive waypoint-pass-through value Nₜ at the time t using Equation 1 below.

$$[ Math . 1 ]$$

$${N}_{t} = {k}_{1} {{\sum }^{G}}_{i = 1} {D}_{t + 1 , i} + {k}_{2} {{\sum }^{G}}_{i = 1} {D}_{t + 2 , i} + … + {k}_{g} {{\sum }^{G}}_{i = 1} {D}_{t + g , i} + {γ}_{1} {{\sum }^{G}}_{i = 1} {A}_{t - 1 , i} + {γ}_{2} {{\sum }^{G}}_{i = 1} {A}_{t - 2 , i} + … + {γ}_{s} {{\sum }^{G}}_{i = 1} {A}_{t - s , i} \qquad ( 1 )$$

In Equation 1, G is the number of the first points A as well as the number of the second points C. In the example of Equation 1, the number of the first points A and the number of the second points C are the same value of G. However, the number of the first points A and the number of the second points C, that is, G for the first points A and G for the second points C may be different.

Additionally, in Equation 1, D_{t+1, i} is a predictive value of the number of the people U located at the second point C at the future time t+1 after the predetermined time t (the second predictive value of one of the second points C at the future time t+1). Here, the future times are delayed “1” by “1” with respect to the predetermined time t, such as t+1, t+2, . . . , t+g. That is, the interval between the future times is “1”. The interval (“1”) between the future times here may be 1 hour but is not limited thereto. The interval between the future times may be any length of time, and “1” can be said as a standardized value of the interval between the future times. The interval between the future times also may not to be constant. In addition, g, which is the number of the future times, may be any positive number. In Equation 1, k is the influence degree set for the second predictive value and is a value from 0 to 1. Here, k₁ is the influence degree for the second predictive value at the future time t+1, and k₂ is the influence degree for the second predictive value at the future time t+2, and k_{g} is the influence degree for the second predictive value at the future time t+g.

Additionally, in Equation 1, A_{t-1, i} is a predictive value of the number of the people U located at the first point A at the past time t−1 before the predetermined time t (the first predictive value of one of the first points A at the past time t−1). Here, the past times go back “1” by “1” with respect to the predetermined time t, such as t−1, t−2, . . . , t−s. That is, the interval between the past times is “1”. The interval (“1”) between the past times here may be 1 hour but is not limited thereto. The interval between the past times may be any length of time, and “1” can be said as a standardized value of the interval between the past times. The interval between the past times also may not to be constant. In addition, s, which is the number of the past times, may be any positive number. In Equation 1, γ is the influence degree set for the first predictive value and is a value from 0 to 1. Here, γ₁ is the influence degree for the first predictive value at the past time t−1, γ₂ is the influence degree for the first predictive value at the past time t−2, and γₛ is the influence degree for the first predictive value at the past time t−s.

In this manner, the predictive waypoint-pass-through value calculation unit 22 adds up the first total value (a sum of values of the respective past times obtained by multiplying a total value of the first predictive values of the respective first points A by the corresponding influence degree) and the second total value (a sum of values of the respective future times obtained by multiplying a total value of the second predictive values of the respective second points C by the corresponding influence degree) to calculate the predictive waypoint-pass-through value Nₜ. However, the predictive waypoint-pass-through value calculation unit 22 may calculate the predictive waypoint-pass-through value Nₜ by using the first predictive value and/or the second predictive value at the predetermined time t, in addition to the first predictive value at the past time and the second predictive value at the future time. That is, the predictive waypoint-pass-through value calculation unit 22 may calculate the predictive waypoint-pass-through value Nₜ by adding, to the first total value and the second total value, at least one of the product of the total value of the second predictive values of the respective second points C at the predetermined time t and the corresponding influence degree or the product of the total value of the first predictive values of the respective first points A at the predetermined time t and the corresponding influence degree.

Note that in the present embodiment, the predictive waypoint-pass-through value calculation unit 22 preferably calculates the predictive waypoint-pass-through value Nₜ at the time t as in Equation 2 below. That is, the predictive waypoint-pass-through value calculation unit 22 may calculate the predictive waypoint-pass-through value Nₜ by adding up the second total value (the sum of values of the respective future times obtained by multiplying the total value of the second predictive values of the respective second points C by the corresponding influence degree) calculated with g (the number of the future times) as 4, the first total value (the sum of values of the respective past times obtained by multiplying the total value of the first predictive values of the respective first points A by the corresponding influence degree) calculated with s (the number of the past times) as 3, and the product of the total value of the second predictive values of the respective second points C at the predetermined time t and the corresponding influence degree.

$$[ Math . 2 ]$$

$${N}_{t} = {k}_{0} {{\sum }^{G}}_{i = 1} {D}_{t , i} + {k}_{1} {{\sum }^{G}}_{i = 1} {D}_{t + 1 , i} + {k}_{2} {{\sum }^{G}}_{i = 1} {D}_{t + 2 , i} + {k}_{3} {{\sum }^{G}}_{i = 1} {D}_{t + 3 , i} + {k}_{4} {{\sum }^{G}}_{i = 1} {D}_{t + 4 , i} + {γ}_{2} {{\sum }^{G}}_{i = 1} {A}_{t - 2 , i} + {γ}_{3} {{\sum }^{G}}_{i = 1} {A}_{t - 3 , i} + {γ}_{4} {{\sum }^{G}}_{i = 1} {A}_{t - 4 , i} \qquad ( 2 )$$

The predictive waypoint-pass-through value calculation unit 22 may freely set the influence degrees k and γ. For example, the predictive waypoint-pass-through value calculation unit 22 may set the influence degree k for each future time and the influence degree γ for each past time based on a predictive waypoint-pass-through value Nₜ₀ at a time t0 before the present time (predictive waypoint-pass-through value at the time t0 calculated by the above-described method) and a measured waypoint-pass-through value N′ₜ₀ (the number of people actually passing through the waypoint B at the time t0), which is a measured value of the number of people passing through the waypoint B at the time t0. For example, the predictive waypoint-pass-through value calculation unit 22 calculates a difference between the predictive waypoint-pass-through value Nₜ₀ and the measured waypoint-pass-through value N′ₜ₀ for each time the influence degree k for each future time and the influence degree γ for each past time are changed and sets the influence degree k for each future time and the influence degree γ for each past time minimizing the difference as the influence degrees k and γ to be used for calculation of the predictive waypoint-pass-through value Nₜ at the predetermined time t. Note that the time t0 may be freely set. The influence degrees k and γ are not limited to being set based on the predictive waypoint-pass-through value Nₜ₀ and the measured waypoint-pass-through value N′ₜ₀ at the single time t0. The influence degrees k and γ may be set based on the predictive waypoint-pass-through values and the measured waypoint-pass-through values at a plurality of times.

$$[ Math . 3 ]$$

$$minimize {\sum }_{t 0} {( {N}_{t 0} - {N}_{t 0}^{′} )}^{2} \qquad ( 3 )$$

As described above, the predictive waypoint-pass-through value calculation unit 22 calculates the predictive waypoint-pass-through value at the predetermined time t based on both the first predictive value at the past time and the second predictive value at the future time, but the embodiment is not limited thereto. The predictive waypoint-pass-through value calculation unit 22 may calculate the predictive waypoint-pass-through value at the predetermined time t based on at least one of the first predictive value at the past time or the second predictive value at the future time. Furthermore, the predictive waypoint-pass-through value calculation unit 22 may calculate the predictive waypoint-pass-through value for each of the plurality of predetermined times t while changing the predetermined times t.

In this way, the predictive waypoint-pass-through value is calculated by using the first predictive value at the past time and the second predictive value at the future time, and thus the predictive waypoint-pass-through value can be said as a predictive value of the number of people passing through the waypoint B, which is calculated in consideration that the arrival time to the waypoint B deviates from the reference arrival time to the waypoint B.

### People Flow Information Setting Unit

The people flow information setting unit 24 sets people flow information based on the predictive waypoint-pass-through value at the predetermined time t. The people flow information is information indicating a flow of people between two points in the facility F and is a so-called Origin-Destination (OD) data. That is, the people flow information can be said as data indicating the number of people moving from one point to another point in a unit time. The people flow information is set for each point in the facility F, and thus it can be said that the people flow information indicates the number of people moving between each pair of points. The people flow information setting unit 24 may set, as the people flow information, an OD matrix indicating the number of people moving between two points in a matrix form. The people flow information setting unit 24 may set the people flow information by any method based on the predictive waypoint-pass-through value but may set the people flow information based on, for example, past movement information of the people U in the facility F. The past movement information of the people U is information indicating an actual flow of people between two points in the past (actual value of the number of people moving between two points in the past). For example, the people flow information setting unit 24 may set the people flow information based on the predictive waypoint-pass-through value and the past movement information of the people U, by using a machine learning technique. In this case, for example, the predictive waypoint-pass-through value calculated in the past and the past actual value of the number of people moving between two points at that time are input to an Artificial Intelligence (AI) model before learning, and the AI model is caused to perform machine learning of a correspondence between the predictive waypoint-pass-through value and the number of people moving the two points. Then, the people flow information setting unit 24 inputs the predictive waypoint-pass-through value at the predetermined time t, which is calculated at this time, to the machine-learned AI model, acquires output data indicating the number of people moving between the two points output from the AI model, and sets the output data as the people flow information.

### Operation Condition Setting Unit

The operation condition setting unit 26 calculates, based on the people flow information set by the people flow information setting unit 24 and the facility model MF, which is a simulation model indicating the layout of the facility F, the movement route of each of the people U in a facility model MF and the operation condition of the vehicle TR in the facility model MF by optimization calculation and sets the operation condition of the vehicle TR in the actual facility F. The specific description will be given below.

The operation condition setting unit 26 acquires the facility model MF. The facility model MF is a model indicating the layout of the facility F and can be said as a model in which the space in the facility F is considered as a graph structure. The facility model MF is set such that each point in the facility F is a node, and each passage connecting the points is a link. The operation condition setting unit 26 may acquire the facility model MF by any method. For example, the operation condition setting unit 26 may set (construct) the facility model MF by itself, read the facility model MF stored in the storage unit 12 in advance, or acquire the facility model MF from an external device or the like via the communication unit 10.

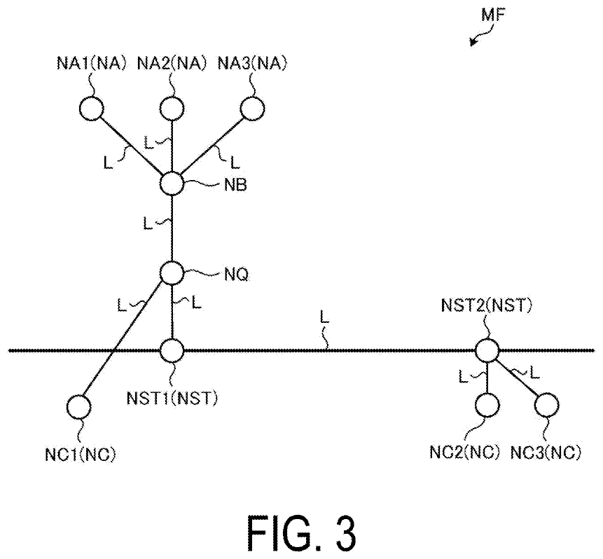

FIG. 3 is a schematic view illustrating an example of the facility model. FIG. 3 illustrates an example of the facility model MF of the facility F illustrated in FIG. 1. As illustrated in FIG. 3, the facility model MF in this example includes nodes NA1, NA2, and NA3 (node NA) corresponding to the first points A1, A2, and A3, respectively, a node NB corresponding to the waypoint B, a node NQ corresponding to a position branching to the point ST1 being a station and the second point C1 from the waypoint B, nodes NST1 and NST2 (node NST) corresponding to the points ST1 and ST2 being stations, respectively, and nodes NC1, NC2 and NC3 (node NC) corresponding to the second points C1, C2, and C3, respectively. Each of the nodes NA1, NA2, and NA3 is connected to the node NB by a link L. The node NB and the node NC1 are connected by links L via the node NQ. The node NB and the node NST1 are connected by links L. The node NST1 and the node NST2 are connected by a link L. The node NST2 is connected to each of the nodes NC2 and NC3 by a link L. The link L connecting the node NST1 and the node NST2 is set as a passage where the vehicle TR runs, and the other links L are set as passages where the vehicle TR does not run and the people U travel, for example, on foot.

The operation condition setting unit 26 combines the movement model of the people U and the movement model of the vehicle TR and performs optimization calculation on the facility model MF, thereby calculating the optimized movement route of each of the people U in the facility model MF and the optimized operation condition of the vehicle TR in the facility model MF. That is, the operation condition setting unit 26 executes, on the facility model MF, simulation in which movement of both the people U and the vehicle TR and transportation of the people U by the vehicle TR are simulated. Thus, the operation condition setting unit 26 calculates the movement route of each of the people U and the operation condition of the vehicle TR in the facility model MF. The movement model of the people U is a model (input condition to the facility model MF) indicating how the people U move in the facility model MF and may include, for example, the movement speed of each of the people U. The movement model of the vehicle TR is a model (input condition to the facility model MF) indicating how the vehicle TR moves in the facility model MF and may include, for example, the movement speed of the vehicle TR. As the movement model of the vehicle TR, for example, a micro model that simulates the behavior of the individual vehicle TR, or a macro model that treats the flow of the vehicles as a fluid may be used.

Specifically, the operation condition setting unit 26 inputs, to the facility model MF, the people flow information (information of the number of people moving between each pair of nodes in the facility model MF), the movement model of the people U, the movement model of the vehicle TR, and a predetermined constraint condition and performs optimization calculation. As the movement route of each of the people U, the operation condition setting unit 26 sets, for each of the people U, a node corresponding to the first point A as the departure point, a node corresponding to the second point C as the arrival point, and a route from the node as the departure point to the node as the arrival point via a node corresponding to the waypoint B. The operation condition setting unit 26 may set the movement route of each of the people U by any method. For example, the operation condition setting unit 26 may set the movement route of each of the people U by a method called User Equilibrium so as to minimize the total of the movement time of each of the people U.

The operation condition setting unit 26 sets the operation condition of the vehicle TR in the facility model MF so as to optimize the operation condition of the vehicle TR under the condition that each of the people U moves along the set movement route in the facility model MF and a predetermined constraint condition is satisfied. Here, the constraint condition may be freely set, but examples of the constraint condition may include the maximum waiting time of each of the people U at the node ST being a station, and the maximum number of the vehicles TR in operation (the maximum number of units of the vehicle TR that can operate simultaneously). Furthermore, in the present embodiment, the operation condition of the vehicle TR subjected to the optimization calculation is an operation schedule of the vehicle TR (information indicating the arrival time and the departure time of the vehicle TR at a node corresponding to each station). However, the operation condition of the vehicle TR subjected to the optimization calculation may not be limited thereto and may be any condition. Examples of the operation condition of the vehicle TR may include the number of vehicle bodies of one unit of the vehicle TR, in addition to the operation schedule.

The operation condition setting unit 26 outputs information regarding the optimized operation condition of the vehicle TR in the facility model MF, which is calculated by the optimization calculation. The operation condition setting unit 26 may output (transmit) the information regarding the optimized operation condition of the vehicle TR to an external device via the communication unit 10 or may display the information on a display unit (not illustrated). The operation condition setting unit 26 sets the information regarding the optimized operation condition of the vehicle TR in the facility model MF as the actual operation condition of the vehicle TR.

### Processing Flow

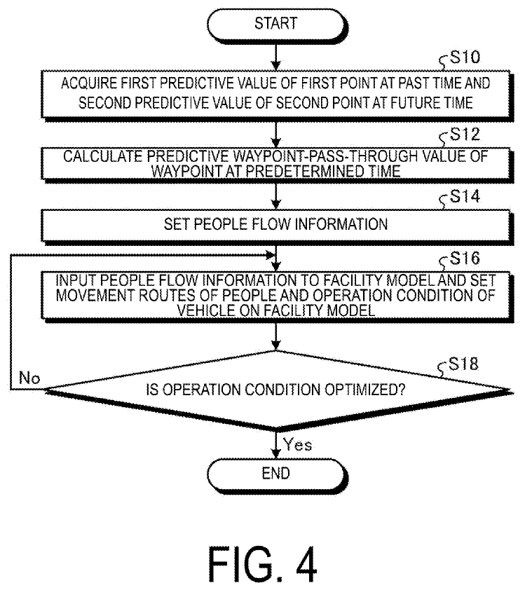

Processing flow of the above-described operation condition setting device 100 will be described with reference to a flowchart. FIG. 4 is a flowchart for describing processing flow of the operation condition setting device according to the present embodiment. As illustrated in FIG. 4, the operation condition setting device 100 causes the predictive value acquisition unit 20 to acquire the first predictive value, which is a predictive value of the number of the people U at the first point A in the past time, and a second predictive value, which is a predictive value of the number of the people U at the second point C in the future time (step S10). Then, the operation condition setting device 100 causes the predictive waypoint-pass-through value calculation unit 22 to calculate the predictive waypoint-pass-through value, which is a predictive value of the number of the people U passing through the waypoint B at the predetermined time t (step S12). The operation condition setting device 100 causes the people flow information setting unit 24 to set the people flow information indicating a flow of people between two points based on the predictive waypoint-pass-through value (step S14). Then, the operation condition setting device 100 causes the operation condition setting unit 26 to input the people flow information to the facility model MF and set the movement route of each of the people U on the facility model MF and the operation condition of the vehicle TR on the facility model MF, by the optimization calculation (step S16). The operation condition setting unit 26 checks whether the set operation condition of the vehicle TR is optimized (step S18). If the operation condition is not optimized (No in step S18), the processing returns to step S16, and the optimization calculation continues. On the other hand, if the operation condition is optimized (Yes in step S18), the set operation condition of the vehicle TR is output, and the processing ends.

### Effect

Here, in order to appropriately set the operation condition of the vehicle TR, it is demanded to predict the number of the people U (people flow) who may use the vehicle TR with high accuracy. In contrast, the operation condition setting device 100 according to the present embodiment sets the operation condition of the vehicle TR based on the predictive waypoint-pass-through value of the number of people passing through the waypoint B. In the facility F, the plurality of people U pass through the common waypoint B, and thus the operation condition setting device 100 can predict the flow of people who may use the vehicle TR with high accuracy by predicting the number of people passing through the waypoint B and set the operation condition of the vehicle TR that can transport the number of people appropriately. In addition, the operation condition setting device 100 sets the operation condition of the vehicle TR based on the predictive waypoint-pass-through value, which is calculated in consideration that the arrival time to the waypoint B deviates from the reference arrival time to the waypoint B, of the number of people passing through the waypoint B. Accordingly, by using the predictive waypoint-pass-through value calculated in consideration of the time deviation from the scheduled time when the waypoint B is passed through, the people flow can be predicted with even higher accuracy, and the operation condition of the vehicle TR can be set.

In addition, the operation condition setting device 100 according to the present embodiment calculates the predictive waypoint-pass-through value of the number of the people U passing through the waypoint B at the predetermined time t, based on the first predictive value of the number of the people U at the first point A in the past time before the predetermined time t and the second predictive value of the number of the people U at the second point C in the future time after the predetermined time t. Thus, according to the present embodiment, even in a case where there is a time deviation from the scheduled time when the waypoint B is passed through, such as a case where people pass through the waypoint B at different times with respect to the departure time of an airplane or a case where the travel speed of each of the people is slow during congestion, the predictive waypoint-pass-through value can be calculated with such a time deviation absorbed. Thus, according to the present embodiment, the people flow can be predicted with high accuracy, in consideration of the time deviation.

### People Flow Prediction Device

In the above description, the operation condition setting device 100 sets the operation condition of the vehicle TR based on the predictive waypoint-pass-through value at the predetermined time t, but use of the predictive waypoint-pass-through value at the predetermined time t is not limited to setting of the operation condition of the vehicle TR, and the predictive waypoint-pass-through value may be used for any purpose. That is, in the present embodiment, the operation condition setting device 100 is not essential, and a people flow prediction device 100A may calculate and output the predictive waypoint-pass-through value at the predetermined time t.

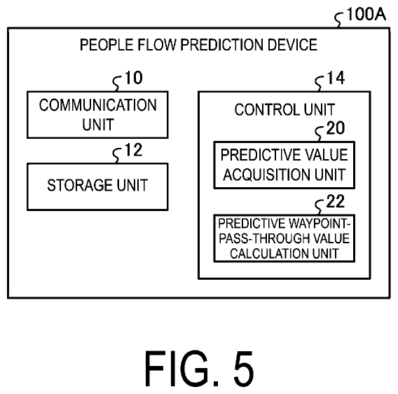

FIG. 5 is a schematic block diagram of the people flow prediction device. As illustrated in FIG. 5, the people flow prediction device 100A includes a communication unit 10, a storage unit 12, and a control unit 14. The control unit 14 includes a predictive value acquisition unit 20 and a predictive waypoint-pass-through value calculation unit 22. The predictive value acquisition unit 20 of the people flow prediction device 100A acquires the first predictive value and the second predictive value in a manner similar to the above-described operation condition setting device 100. The predictive waypoint-pass-through value calculation unit 22 of the people flow prediction device 100A calculates the predictive waypoint-pass-through value based on the first predictive value and the second predictive value and outputs the predictive waypoint-pass-through value, in a manner similar to the above-described operation condition setting device 100. The predictive waypoint-pass-through value calculation unit 22 may output (transmit) the predictive waypoint-pass-through value to an external device via the communication unit 10 or display the predictive waypoint-pass-through value on a display unit (not illustrated).

### Second Embodiment

Next, a second embodiment will be described. The second embodiment is different from the first embodiment in that the influence degrees k and γ are different for each time slot of the predetermined time t. Parts of the second embodiment with configurations that are the same as those in the first embodiment will not be described.

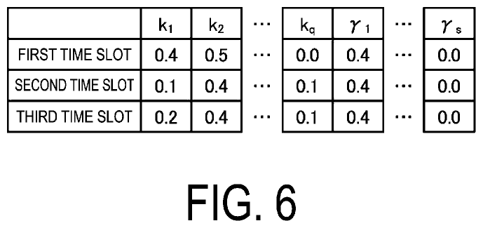

FIG. 6 is a table showing examples of values of the influence degrees of each time slot of the predetermined time. The predictive waypoint-pass-through value calculation unit 22 of the second embodiment sets, for each time slot of the predetermined time t, the influence degree γ for the first predictive values at the respective past times and the influence degree k for the second predictive values at the respective future times. That is, for example, as shown in FIG. 6, the predictive waypoint-pass-through value calculation unit 22 calculates the influence degrees k and γ when the predetermined time t is in a first time slot, the influence degrees k and γ when the predetermined time t is in a second time slot (e.g., time slot in the daytime), and the influence degrees k and γ when the predetermined time t is in a third time slot (e.g., time slot at night). The first time slot is, for example, a time slot in the morning. The second time slot is a time slot later than the first time slot and is, for example, a time slot in the daytime. The third time slot is a time slot later than the second time slot and is, for example, a time slot at night. However, each time slot may be freely set, and the number of the time slots in which the influence degrees k and γ are individually set is not limited to three and may be any number. The numerical values of the influence degrees k and γ of each time slot illustrated in FIG. 6 are mere examples.

For example, based on the predictive waypoint-pass-through value at a past time belonging to a time slot in which the influence degrees k and γ are to be individually set and the measured waypoint-pass-through value at that time, the predictive waypoint-pass-through value calculation unit 22 sets the influence degrees k and γ in that time slot. That is, for example, the predictive waypoint-pass-through value calculation unit 22 sets the influence degrees k and γ in the first time slot based on the predictive waypoint-pass-through value at a time that is before the present time and belongs to the first time slot and a measured waypoint-pass-through value, which is a measured value of the number of people passing through the waypoint B at that time. Similarly, the predictive waypoint-pass-through value calculation unit 22 sets the influence degrees k and γ in the second time slot based on the predictive waypoint-pass-through value at a time that is before the present time and belongs to the second time slot and a measured waypoint-pass-through value, which is a measured value of the number of people passing through the waypoint B at that time.

The predictive waypoint-pass-through value calculation unit 22 acquires the influence degrees k and γ set for the time slot overlapping the predetermined time t to be subjected to calculation of the predictive waypoint-pass-through value and calculates the predictive waypoint-pass-through value by using the acquired influence degrees k and γ. That is, for example, when calculating the predictive waypoint-pass-through value at the predetermined time t belonging to the first time slot, the predictive waypoint-pass-through value calculation unit 22 calculates the predictive waypoint-pass-through value by using the influence degrees k and γ set for the first time slot. By individually setting the influence degrees k and γ for each time slot in this manner, the predictive waypoint-pass-through value calculation unit 22 can make the influence degrees k and γ different for each time slot of the predetermined time t.

In this manner, the influence degrees k and γ are set by using the past data for each time slot, and the influence degrees k and γ are made different for each time slot. Thus, the movement pattern of each of the people U in accordance with the time slot can be reflected on the predictive waypoint-pass-through value, so that the predictive waypoint-pass-through value can be calculated with even higher accuracy. That is, for example, a public transportation system to the airport does not work in the first time slot in the early morning, and many travelers tend to come just before the departure of an airplane. In contrast, by setting the influence degrees k and γ for each time slot based on the past data, for example, k₁ and k₂ can be set to be higher than k_{g}, with reflection of the tendency in the first time slot. Thus, the movement pattern of each of the people U in accordance with the time slot can be appropriately reflected in the predictive waypoint-pass-through value.

### Third Embodiment

Next, a third embodiment will be described. The third embodiment is different from the first embodiment in that the operation condition of each vehicle TR is set under a constraint condition that the number of vehicle bodies of each vehicle TR is the same. In the third embodiment, the description of parts having the same configuration as those in the first embodiment will be omitted. The third embodiment can also be applied to the second embodiment.

In the third embodiment, each vehicle TR includes a plurality of vehicle bodies, and each vehicle body is configured to allow passengers to get thereon. For example, the plurality of vehicle bodies of the vehicle TR may be coupled in series. In the third embodiment, the operation condition setting unit 26 performs optimization calculation of setting the operation condition of each vehicle TR under the constraint condition that each vehicle TR includes the same number of vehicle bodies. That is, the operation condition setting unit 26 sets the operation condition of each vehicle TR so as to reduce the number of vehicle bodies per unit of the vehicle TR as much as possible under the constraint condition that each vehicle TR includes the same number of vehicle bodies. In this case, the operation condition setting unit 26 calculates the number of vehicle bodies X, which is the number of vehicle bodies included in each vehicle TR, based on Equation 4 below, adds the number of vehicle bodies X to the constraint condition, and performs optimization calculation of setting the operation condition of each vehicle TR.

[Math. 4]

X=Ymax·RTT/(Z·Y) (4)

Here, Yₘₐₓ is the maximum number of passengers per unit time and is calculated based on, for example, the people flow information. That is, the operation condition setting unit 26 determines whether the people U use the vehicle TR for each of the people U, based on the departure point and the arrival point indicated by the people flow information (the source point of movement and the destination point of movement among two points) and adds the number of the people U to the number of passengers as Ymax, if the vehicle TR is determined to be used. The method of determining whether to use the vehicle TR based on the people flow information may be any method, but for example, if the operation route of the vehicle TR is present on the route between the departure point and the arrival point, the vehicle TR may be determined to be used. In addition, a Round Trip Time (RTT) is a time used for one unit of the vehicle TR to make a round trip of the operation route (go around the operation route). Z is the maximum number of units of the vehicles TR that can operate simultaneously, and Y is the passenger capacity of one vehicle body. RTT, Z, and Y may be set in advance.

In this manner, in the third embodiment, the operation condition setting unit 26 sets the operation condition (operation schedule) of each vehicle TR under the constraint condition that each vehicle TR includes the same number of vehicle bodies. Accordingly, the operation condition can be set so that the number of vehicle bodies per unit of the vehicle TR is reduced as much as possible while the number of vehicle bodies per unit is fixed. Thus, a change in the operation condition in response to a passenger demand can be easily handled by changing the number of units of the operating vehicles TR, not the number of vehicle bodies. This can reduce work for coupling or decoupling the vehicle bodies.

### Fourth Embodiment

Next, a fourth embodiment will be described. In the fourth embodiment, an acquisition method of the first predictive value and the second predictive value is different from that of the first embodiment. In the fourth embodiment, the description of parts having the same configuration as those in the first embodiment will be omitted. The fourth embodiment can be also applied to the second embodiment and the third embodiment.

In the first embodiment, the predictive value acquisition unit 20 acquires the number of reservations of passengers of an airplane arriving at the first point A and the number of passengers of an airplane departing from the second point C as the first predictive value and the second predictive value, respectively. However, the first predictive value and the second predictive value may be calculated based on the capacity of an airplane, for example, when the number of passengers of the airplane is unknown in advance. In this case, for example, the predictive value acquisition unit 20 may use the product of the capacity of the airplane arriving at the first point A in the past time and a predetermined Load Factor, as the first predictive value of the first point A at the past time. Similarly, the predictive value acquisition unit 20 may use the product of the capacity of the airplane departing from the second point C at the future time and a predetermined Load Factor, as the second predictive value of the second point C at the future time. The Load Factor may be freely set and, for example, set for each airplane.

The predictive waypoint-pass-through value calculation unit 22 of the fourth embodiment calculates the predictive waypoint-pass-through value based on the first predictive value and the second predictive value calculated as described above in a manner similar to that of the first embodiment. That is, the predictive waypoint-pass-through value calculation unit 22 preferably calculates the predictive waypoint-pass-through value Nₜ₀, by using Equation 5 below.

$$[ Math . 5 ]$$

$${N}_{t} = {k}_{1} {{\sum }^{G}}_{i = 1} {λ}_{t , i} {D}_{t , i}^{′} + {k}_{2} {{\sum }^{G}}_{i = 1} {λ}_{t + 1 , i} {D}_{t + 1 , i}^{′} + {k}_{3} {{\sum }^{G}}_{i = 1} {λ}_{t + 2 , i} {D}_{t + 2 , i}^{′} + {k}_{4} {{\sum }^{G}}_{i = 1} {λ}_{t + 3 , i} {D}_{t + 3 , i}^{′} + {k}_{5} {{\sum }^{G}}_{i = 1} {λ}_{t + 4 , i} {D}_{t + 4 , i}^{′} + {γ}_{2} {{\sum }^{G}}_{i = 1} {λ}_{t - 2 , i} {A}_{t - 2 , i}^{′} + {γ}_{3} {{\sum }^{G}}_{i = 1} {λ}_{t - 3 , i} {A}_{t - 3 , i}^{′} + {γ}_{4} {{\sum }^{G}}_{i = 1} {λ}_{t - 4 , i} {A}_{t - 4 , i}^{′} \qquad ( 5 )$$

In Equation 5, λ_{t, i} is a Load Factor at the predetermined time t. In addition, D′_{t, i} is the capacity of an airplane departing from the second point C at the predetermined time t, and A′_{t-2, i} is the capacity of an airplane arriving at the first point A in the past time t−2.

In this manner, by calculating the first predictive value and the second predictive value based on the capacity of the airplane, the predictive waypoint-pass-through value can be appropriately calculated, for example, even when the number of passengers in the airplane is unknown in advance.

### Effect

As described above, the operation condition setting device 100 according to the disclosure sets the operation condition of the vehicle TR transporting people between predetermined points in the facility F including the waypoint B through which the people U pass and includes the predictive waypoint-pass-through value calculation unit 22, the people flow information setting unit 24, and the operation condition setting unit 26. The predictive waypoint-pass-through value calculation unit 22 acquires the predictive waypoint-pass-through value, which is a predictive value of the number of people passing through the waypoint B at the predetermined time tin the future and is calculated in consideration that the arrival time to the waypoint B deviates from the reference arrival time to the waypoint B. The people flow information setting unit 24 sets the people flow information indicating a flow of people in the facility F based on the predictive waypoint-pass-through value. The operation condition setting unit 26 calculates, based on the facility model MF including the node corresponding to each point in the facility F and the link connecting the nodes and the people flow information, the movement route of each of the people passing through the waypoint B in the facility model MF and the operation condition of the vehicle TR, by performing optimization calculation and sets the operation condition of the vehicle TR.

The operation condition setting device 100 according to the disclosure sets the operation condition of the vehicle TR based on the predictive waypoint-pass-through value of the number of people passing through the waypoint B. The operation condition setting device 100 can predict the flow of people that may use the vehicle TR with high accuracy, by predicting the number of people passing through the waypoint B and set the operation condition of the vehicle TR that can transport the number of people appropriately. In addition, the operation condition setting device 100 sets the operation condition of the vehicle TR based on the predictive waypoint-pass-through value, which is calculated in consideration that the arrival time to the waypoint B deviates from the reference arrival time to the waypoint B, of the number of people passing through the waypoint B. Accordingly, by using the predictive waypoint-pass-through value calculated in consideration of the time deviation from the scheduled time when the waypoint B is passed through, the people flow can be predicted with even higher accuracy, and the operation condition of the vehicle TR can be set.

Furthermore, the predictive waypoint-pass-through value calculation unit 22 calculates the predictive waypoint-pass-through value based on the predictive value (first predictive value) of the number of people located at the first point A upstream from the waypoint B in the movement direction of the people U before the predetermined time t. Accordingly, even when there is a time deviation from the scheduled time when the waypoint B is passed through, the people flow can be predicted with high accuracy, by calculating the predictive waypoint-pass-through value while absorbing the time deviation.

Furthermore, the predictive waypoint-pass-through value calculation unit 22 calculates the predictive waypoint-pass-through value based on the first predictive value of the number of people located at the first point A in each of the different past times before the predetermined time t and the influence degree γ on the predictive waypoint-pass-through value set for the first predictive value at each past time. According to the disclosure, the predictive waypoint-pass-through value is calculated based on the first predictive value at each past time where the influence degree γ is taken into account, and thus the people flow can be predicted with high accuracy while the time deviation from the scheduled time when the waypoint B is passed through is more suitably taken into account.

Furthermore, the predictive waypoint-pass-through value calculation unit 22 calculates the predictive waypoint-pass-through value based on the predictive value (second predictive value) of the number of people located at the second point C downstream from the waypoint B in the movement direction of the people U after the predetermined time t. Accordingly, even when there is a time deviation from the scheduled time when the waypoint B is passed through, the people flow can be predicted with high accuracy, by calculating the predictive waypoint-pass-through value while absorbing the time deviation.

Furthermore, the predictive waypoint-pass-through value calculation unit 22 calculates the predictive waypoint-pass-through value based on the second predictive value of the number of people located at the second point C in each of the different future times after the predetermined time t and the influence degree k on the predictive waypoint-pass-through value set for the second predictive value at each future time. According to the disclosure, the predictive waypoint-pass-through value is calculated based on the second predictive value at each future time where the influence degree k is taken into account, and thus the people flow can be predicted with high accuracy while the time deviation from the scheduled time when the waypoint B is passed through is more suitably taken into account.

Furthermore, the predictive waypoint-pass-through value calculation unit 22 sets the influence degree based on the measured waypoint-pass-through value N′ₜ₀, which is a measured value of the number of people passing through the waypoint B at the past time t0 and the predictive waypoint-pass-through value Nₜ₀ at the past time to. According to the disclosure, the influence degree is set based on the past actual measured data and the past prediction data, and thus the predictive waypoint-pass-through value can be calculated with high accuracy.

Furthermore, the predictive waypoint-pass-through value calculation unit 22 makes the influence degree different for each time slot of the predetermined time t subjected to calculation of the predictive waypoint-pass-through value. According to the disclosure, the movement pattern of each of the people U in accordance with the time slot can be reflected on the predictive waypoint-pass-through value, and thus the predictive waypoint-pass-through value can be calculated with even higher accuracy.

The people flow information setting unit 24 sets the people flow information based on the past movement information of people in the facility F. According to the disclosure, the people flow information can be predicted with high accuracy by using the past movement information of people.

In addition, the operation condition setting unit 26 sets the movement route of each of the people U so as to minimize the total value of the movement time of each of the people U in the facility model MF. According to the disclosure, the movement route of each of the people U can be predicted with high accuracy.

In addition, the operation condition setting unit 26 sets the operation schedule of the vehicle TR as the operation condition of the vehicle TR. According to the disclosure, the flow of people is predicted with high accuracy in consideration of the time deviation, and thus the operation schedule of the vehicle TR can be appropriately set.

Furthermore, the operation condition setting unit 26 sets the operation condition of the vehicle TR in which the plurality of vehicle bodies are coupled and sets the operation schedule of the vehicle TR under the constraint condition that each vehicle TR includes the same number of vehicle bodies. According to the disclosure, the operation condition can be set so that the number of vehicle bodies per vehicle TR is reduced as much as possible while the number of vehicle bodies of each vehicle TR is fixed.

The facility F is an airport, and the waypoint B is a security check point in the airport. According to the disclosure, the operation condition of the vehicle TR operating in such an airport can be appropriately set.

The people flow prediction device 100A according to the disclosure predicts the number of people passing through the waypoint B at the predetermined time t in the future in the facility F including the waypoint B through which the people U pass and includes the predictive value acquisition unit 20 and the predictive waypoint-pass-through value calculation unit 22. The predictive value acquisition unit 20 acquires at least one of the first predictive value, which is a predictive value of the number of people located at the first point A upstream from the waypoint B in the movement direction of the people U before the predetermined time t, or the second predictive value, which is a predictive value of the number of people located at the second point C downstream from the waypoint B in the movement direction of the people U after the predetermined time t. The predictive waypoint-pass-through value calculation unit 22 calculates the predictive waypoint-pass-through value, which is a predictive value of the number of people passing through the waypoint B at the predetermined time t, based on at least one of the first predictive value or the second predictive value. According to the disclosure, the flow of people can be predicted with high accuracy in consideration of a time deviation.

The embodiments of the disclosure are described above, but the embodiment is not limited by the details of the embodiments above. Furthermore, the constituent elements of the above-described embodiments include elements that are able to be easily conceived by a person skilled in the art, and elements that are substantially the same, that is, elements of an equivalent scope. Furthermore, the constituent elements described above can be appropriately combined. Furthermore, it is possible to make various omissions, substitutions, and changes to the constituent elements within a range not departing from the scope of the above-described embodiments.

While preferred embodiments of the invention have been described as above, it is to be understood that variations and modifications will be apparent to those skilled in the art without departing from the scope and spirit of the invention. The scope of the invention, therefore, is to be determined solely by the following claims.

1. An operation condition setting device setting an operation condition of a vehicle transporting people between predetermined points in a facility including a waypoint where people pass, the operation condition setting device comprising:
a predictive waypoint-pass-through value calculation unit configured to calculate a predictive waypoint-pass-through value, the predictive waypoint-pass-through value being a predictive value of the number of people passing through the waypoint at a predetermined time in a future and being calculated in consideration that an arrival time to the waypoint deviates from a reference arrival time to the waypoint;
a people flow information setting unit configured to set, based on the predictive waypoint-pass-through value, people flow information indicating a flow of people in the facility; and
an operation condition setting unit configured to calculate, based on a facility model and the people flow information, a movement route for each of the people passing through the waypoint in the facility model and the operation condition of the vehicle, by performing optimization calculation and set the operation condition of the vehicle, the facility model including nodes each corresponding to respective points in the facility and a link connecting the nodes.

2. The operation condition setting device according to claim 1, wherein
the predictive waypoint-pass-through value calculation unit calculates the predictive waypoint-pass-through value based on a predictive value of the number of people located at a first point upstream from the waypoint in a movement direction of people before the predetermined time.

3. The operation condition setting device according to claim 2, wherein
the predictive waypoint-pass-through value calculation unit calculates the predictive waypoint-pass-through value based on respective predictive values of the numbers of people located at the first point at different times before the predetermined time and an influence degree, on the predictive waypoint-pass-through value, set for each of the predictive values at the different times.

4. The operation condition setting device according to claim 1, wherein
the predictive waypoint-pass-through value calculation unit calculates the predictive waypoint-pass-through value based on a predictive value of the number of people located at a second point downstream from the waypoint in a movement direction of people after the predetermined time.

5. The operation condition setting device according to claim 4, wherein
the predictive waypoint-pass-through value calculation unit calculates the predictive waypoint-pass-through value based on respective predictive values of the numbers of people located at the second point at different times after the predetermined time and an influence degree, on the predictive waypoint-pass-through value, set for each of the predictive values at the different times.

6. The operation condition setting device according to claim 3, wherein
the predictive waypoint-pass-through value calculation unit sets the influence degree based on a measured waypoint-pass-through value being a measured value of the number of people passing through the waypoint at a past time, and the predictive waypoint-pass-through value at the past time.

7. The operation condition setting device according to claim 3, wherein
the predictive waypoint-pass-through value calculation unit makes the influence degree different in respective time slots of the predetermined time to be subjected to calculation of the predictive waypoint-pass-through value.

8. The operation condition setting device according to claim 1, wherein
the people flow information setting unit sets the people flow information based on past movement information of people in the facility.

9. The operation condition setting device according to claim 1, wherein
the operation condition setting unit sets the movement routes of people to minimize a total value of movement times of the people in the facility model.

10. The operation condition setting device according to claim 1, wherein
the operation condition setting unit sets, as the operation condition of the vehicle, an operation schedule of the vehicle.

11. The operation condition setting device according to claim 10, wherein
the operation condition setting unit is configured to set the operation condition of the vehicle including a plurality of coupled vehicle bodies and sets, under a constraint condition that a plurality of the vehicles include identical numbers of vehicle bodies, the operation schedule of the vehicle.

12. The operation condition setting device according to claim 1, wherein
the facility is an airport, and the waypoint is a security check point in the airport.

13. A people flow prediction device predicting, in a facility including a waypoint where people pass, the number of people passing through the waypoint at a predetermined time in a future, the people flow prediction device comprising:
a predictive value acquisition unit configured to acquire at least one of a first predictive value or a second predictive value, the first predictive value being a predictive value of the number of people located at a first point upstream from the waypoint in a movement direction of people before the predetermined time, the second predictive value being a predictive value of the number of people located at a second point downstream from the waypoint in the movement direction of the people after the predetermined time; and
a predictive waypoint-pass-through value calculation unit configured to calculate a predictive waypoint-pass-through value based on at least one of the first predictive value or the second predictive value, the predictive waypoint-pass-through value being a predictive value of the number of people passing through the waypoint at the predetermined time, wherein
the predictive waypoint-pass-through value calculation unit
calculates the predictive waypoint-pass-through value based on respective predictive values of the numbers of people located at the first point at different times before the predetermined time and an influence degree, on the predictive waypoint-pass-through value, set for each of the predictive values at the different times before the predetermined time, and
calculates the predictive waypoint-pass-through value based on respective predictive values of the numbers of people located at the second point at different times after the predetermined time and an influence degree, on the predictive waypoint-pass-through value, set for each of the predictive values at the different times after the predetermined time.

14. The people flow prediction device according to claim 13, wherein
the facility is an airport, and the waypoint is a security check point in the airport.

15. An operation condition setting method of setting an operation condition of a vehicle transporting people between predetermined points in a facility including a waypoint where people pass, the operation condition setting method comprising:
calculating a predictive waypoint-pass-through value, the predictive waypoint-pass-through value being a predictive value of the number of people passing through the waypoint at a predetermined time in a future and being calculated in consideration that an arrival time to the waypoint deviates from a reference arrival time to the waypoint;
setting, based on the predictive waypoint-pass-through value, people flow information indicating a flow of people in the facility;
setting, based on a facility model and the people flow information, a movement route of people in the facility model for each of the people passing through the waypoint, the facility model including nodes each corresponding to respective points in the facility and a link connecting the nodes; and
setting the operation condition of the vehicle by calculating the operation condition of the vehicle in the facility model through optimization calculation based on the movement route.

16. A people flow prediction method of predicting, in a facility including a waypoint where people pass, the number of people passing through the waypoint at a predetermined time in a future, the people flow prediction method comprising:
acquiring at least one of a first predictive value or a second predictive value, the first predictive value being a predictive value of the number of people located at a first point upstream from the waypoint in a movement direction of people before the predetermined time, the second predictive value being a predictive value of the number of people located at a second point downstream from the waypoint in the movement direction of the people after the predetermined time; and
calculating a predictive waypoint-pass-through value based on at least one of the first predictive value or the second predictive value, the predictive waypoint-pass-through value being a predictive value of the number of people passing through the waypoint at the predetermined time, wherein
in the calculating,
the predictive waypoint-pass-through value is calculated based on respective predictive values of the numbers of people located at the first point at different times before the predetermined time and an influence degree, on the predictive waypoint-pass-through value, set for each of the predictive values at the different times before the predetermined time, and
the predictive waypoint-pass-through value is calculated based on respective predictive values of the numbers of people located at the second point at different times after the predetermined time and an influence degree, on the predictive waypoint-pass-through value, set for each of the predictive values at the different times after the predetermined time.

17. A non-transitory computer readable storage medium storing a program for causing a computer to execute an operation condition setting method of setting an operation condition of a vehicle transporting people between predetermined points in a facility including a waypoint where people pass, the program causing the computer to execute:
calculating a predictive waypoint-pass-through value, the predictive waypoint-pass-through value being a predictive value of the number of people passing through the waypoint at a predetermined time in a future and being calculated in consideration that an arrival time to the waypoint deviates from a reference arrival time to the waypoint;
setting, based on the predictive waypoint-pass-through value, people flow information indicating a flow of people in the facility;
setting, based on a facility model and the people flow information, a movement route of people in the facility model for each of the people passing through the waypoint, the facility model including nodes each corresponding to respective points in the facility and a link connecting the nodes; and
setting the operation condition of the vehicle by calculating the operation condition of the vehicle in the facility model through optimization calculation based on the movement route.

18. A non-transitory computer readable storage medium storing a program for causing a computer to execute a people flow prediction method of predicting, in a facility including a waypoint where people pass, the number of people passing through the waypoint at a predetermined time in a future, the program causing the computer to execute:
acquiring at least one of a first predictive value or a second predictive value, the first predictive value being a predictive value of the number of people located at a first point upstream from the waypoint in a movement direction of people before the predetermined time, the second predictive value being a predictive value of the number of people located at a second point downstream from the waypoint in the movement direction of the people after the predetermined time; and
calculating a predictive waypoint-pass-through value based on at least one of the first predictive value or the second predictive value, the predictive waypoint-pass-through value being a predictive value of the number of people passing through the waypoint at the predetermined time, wherein
in the calculating,
the predictive waypoint-pass-through value is calculated based on respective predictive values of the numbers of people located at the first point at different times before the predetermined time and an influence degree, on the predictive waypoint-pass-through value, set for each of the predictive values at the different times before the predetermined time, and
the predictive waypoint-pass-through value is calculated based on respective predictive values of the numbers of people located at the second point at different times after the predetermined time and an influence degree, on the predictive waypoint-pass-through value, set for each of the predictive values at the different times after the predetermined time.
